(19) United States
(12) Patent Application Publication
(10) Pub. No.: US 2005/0053256 A1
(43) Pub. Date: Mar. 10, 2005

(54) Portable musical instrument amplifier

(76) Inventor: Neil Fredrick Albert, New York, NY (US)

Correspondence Address: NEIL F. ALBERT;APT 2609, 2600 NETHERLAND AVE, BRONX, NY, 10463, US

(21) Appl. No.: 10/886,316

(22) Filed: Jul. 7, 2004

Related U.S. Application Data
(60) Provisional application No. 60/485,209, filed on Jul. 7, 2003.

(51) Int. Cl. H03G 3/00; H04R 25/00; H04R 1/02

(52) U.S. Cl. 381/388; 381/376; 381/386

(57) ABSTRACT

Portable Musical Instrument Amplifier with A shallow main enclosure which is shaped to house the electronics, a battery supply, and only the diaphram section of a dynamic loudspeaker, A speaker mounted normal to the two largest sides of the shallow cabinet, this side to be used as the conventional baffle, A speaker magnet which lies outside of this main enclosure due to the shallow form of the cabinet, An extension to this main enclosure cabinet which allows cabinet's internal volume to be be extended just sufficiently to surround the speaker magnet, An air passage created by the difference in cross-sectional area of the extension and the magnet it surrounds., An opening in the extension which exhausts the acoustuc energy flowing around the magnet to the ambient space, and

### CROSS REFERENCE TO RELATED APPLICATIONS

This application is based on provisional application Ser. No. 60/485,209, filed on Jul. 7, 2003.

### STATEMENT REGARDING FEDERALLY SPONSORED RESEARCH OR DEVELOPMENT

Not Applicable

### DESCRIPTION OF ATTACHED APPENDIX

Not Applicable

### BACKGROUND OF THE INVENTION

This invention relates generally to the field of electroacoustics and more specifically to a portable Musical Instrument Amplifier.

This invention relates generally to the field of portable amplification for musical instrument performance.

Musical instrument amplifiers are used to increase the the acoustic volume of a performance on a musical instrument in a manner that produces sound faithful to the original instrument for the purpose of enabling the musicians performance to be better heard when the distance from the audience and the musician increases and the loss of sound due to acoustically absorbtive environments. The amplifiers are typically much larger and heavier than the instrument itself and most of them require sufficient electrical power to necessitate being physically (and electrically) connected to a substantially electrical generator, either from the electric utility company or large portable generators. Furthermore, a soly electronic instrument such as the electric guitar produces little sound at all without the use separate electronic device which amplifies instruments electrical signals and converts them into sound. The use of a large amplifier may not be necessary under many circumstances where the musicians merely needs to generate a reasonable accurate sound of the electrified instrument although not at the highest possible sound pressure level. In these situations the it would be helpful if the size a weight of the amplifier added minimally to the equipment carrying burden of the musician and the restrictions dictated by an external electrical power source.

A number of battery operated instrument amplifiers have been produced. Several battery powered instrument/guitar amplifiers have been produced, some use a relatively large loudspeaker and an amplifier requiring a heavy and proprietary rechargeable battery to operate.

Another type of product which itself is relatively unique uses standard household batteries and an enclosure which houses batteries and a small box of just sufficient volume to create an acoustically sealed enclosure which is also of sufficient dimensions to completely house a speaker which together provide good low frequency performance in a size which had been considered the bare minimum to produce sufficient sound quality for a professional musician or serious student of the instrument (Kimball, et al: U.S. Pat. Nos. 3,860,755, 0,240,315) as some other new designs using the latest digital processing and producing exceptionally good sound using standard household batteries, but are substantially larger and heavier in their effort to produce an even higher quality sound from a portable, battery-powered package.

Lastly there is a class of battery powered instruments are extremely small, being approximately 3″×3″×3″ and are powered from a single transistor radio (9 volt) battery and use exceptionally small loudspeakers. These are usually sold as miniature versions of famous manufacturer larger amplifiers. Due to their small size they rely on overdriven electronic amplifiers to produce harmonics which partially replace the fullness of sound which would ordinarily be achieved by better low frequency performance.

The loudspeaker invented by Amar Bose U.S. Pat. No. 3,582,553 also utilized construction which directed sound energy against a reflecting surface, in its case, the wall behind the cabinet and the side which faces away from the listener. A description of the differences follow. There were a plurality of speaker elements in this design with most of the drivers diaphrams radiating toward the reflecting surface. In the invention disclosed the diaphram is not faced away from the audience, but rather principally uses the primarily out of phase acoustic energy generated from the back of the diaphram and allowed to escape in a controlled manner past the speakers magnet with a constriction formed by port which is connect to the cabinets inner volume and encloses magnet. The Bose invention primarily uses a plurality of medium sized speakers, larger than generally used for low frequency and larger than generally used for high frequency sound radiation in an array to improve bass and midrange transient response. The Bose invention uses the refection of these speakers at an oblique angle to the rear wall to enhance the dispersion of the higher frequency a characteristic which inherently degrades as the driver diameter increase.

Another difference is that the invention disclosed does not use a sealed enclosure as does the Bose invention, but in fact, the sound energy which is directed toward the reflecting surface is extracted from an air passage which connect the cabinet inner volume to the outside environment

Based on the intent of this invention the all all of the previous designs are either larger than needed for basically good performance or as in the group of tiny replica amps, are to small to supply clear and full range sound.

### BRIEF SUMMARY OF THE INVENTION

The primary object of the invention is To provide the smallest possible package containing electronics batteries and speaker element consistent with high quality sound.

Another object of the invention is To create a means for extending the usefullness of a small cabinet to be able to house an efficient speaker having a much larger magnet than would otherwise be possible.

Another object of the invention is To enhance the volume and low frequency performance possible from a small speaker cabinet.

A further object of the invention is To create an enclosure whose shape is optimized to house a plurality of standard AA batteries, a battery type having an extremely elongated profile to power the widesr posible range of audio amplifier circuits.

Yet another object of the invention is To utilize the speaker cabinet to employ the cabinet's resting surface in a way which increases volume and when in its operating position.

Other objects and advantages of the present invention will become apparent from the following descriptions, taken in connection with the accompanying drawings, wherein, by way of illustration and example, an embodiment of the present invention is disclosed.

In accordance with a preferred embodiment of the invention, there is disclosed Portable Musical Instrument Amplifier comprising: A shallow main cabinet which is shaped to house the electronics, a battery supply, and only the diaphram section of a dynamic loudspeaker, A speaker mounted normal to the two largest sides of the shallow cabinet, this side to be used as the conventional baffle, A speaker magnet which lies outside of this main enclosure due to the shallow form of the cabinet, An extension to this main enclosure cabinet which allows cabinet's internal volume to be be extended just sufficiently to surround the speaker magnet, An air passage created by the difference in cross-sectional area of the extension and the magnet it surrounds. and an opening in the extension which exhausts the acoustic energy flowing around the magnet to the ambient space

### BRIEF DESCRIPTION OF THE DRAWINGS

The drawings constitute a part of this specification and include exemplary embodiments to the invention, which may be embodied in various forms. It is to be understood that in some instances various aspects of the invention may be shown exaggerated or enlarged to facilitate an understanding of the invention.

FIG. 1 is a perspective view.

FIG. 2 is a perspective view.

FIG. 3 is an exploded view

FIG. 4 is an exploded view.

FIG. 5 is a perspective view with the invention shown hung from the players belt.

FIG. 6 is a perspective view illustrating the retractable legs.

FIG. 7 is a perspective view showing an alternate embodiment of the cabinet extension.

### DETAILED DESCRIPTION OF THE PREFERRED EMBODIMENTS

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

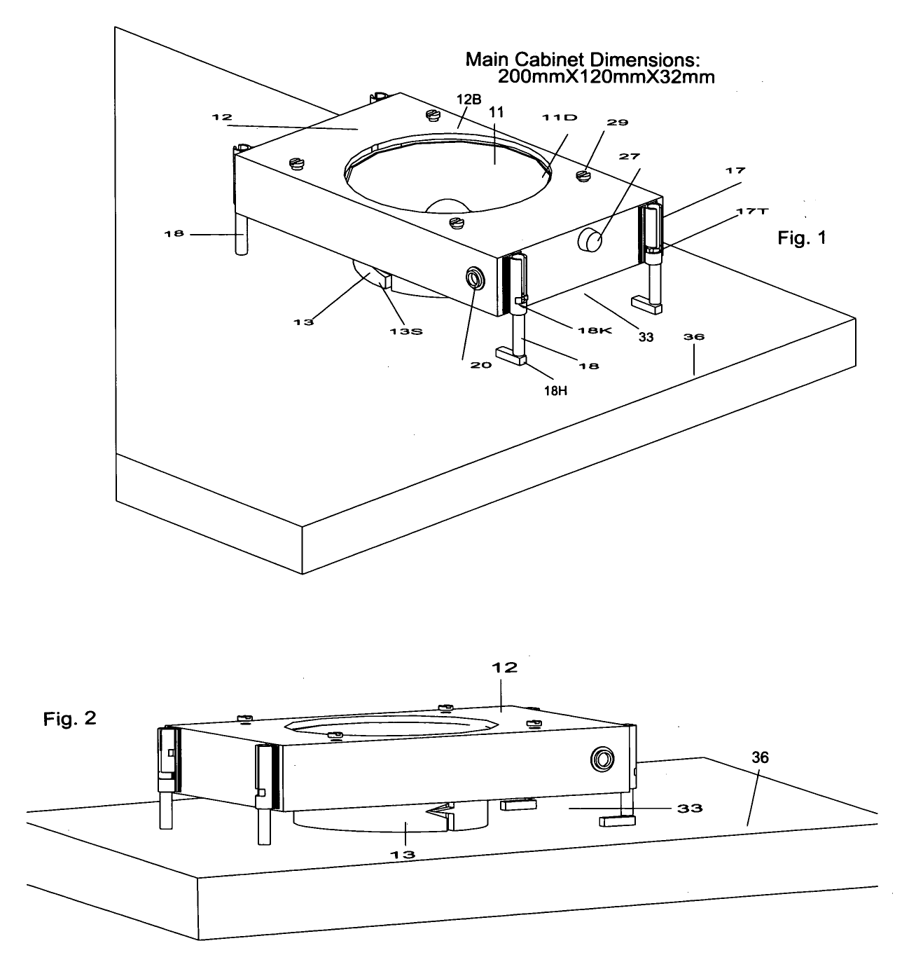

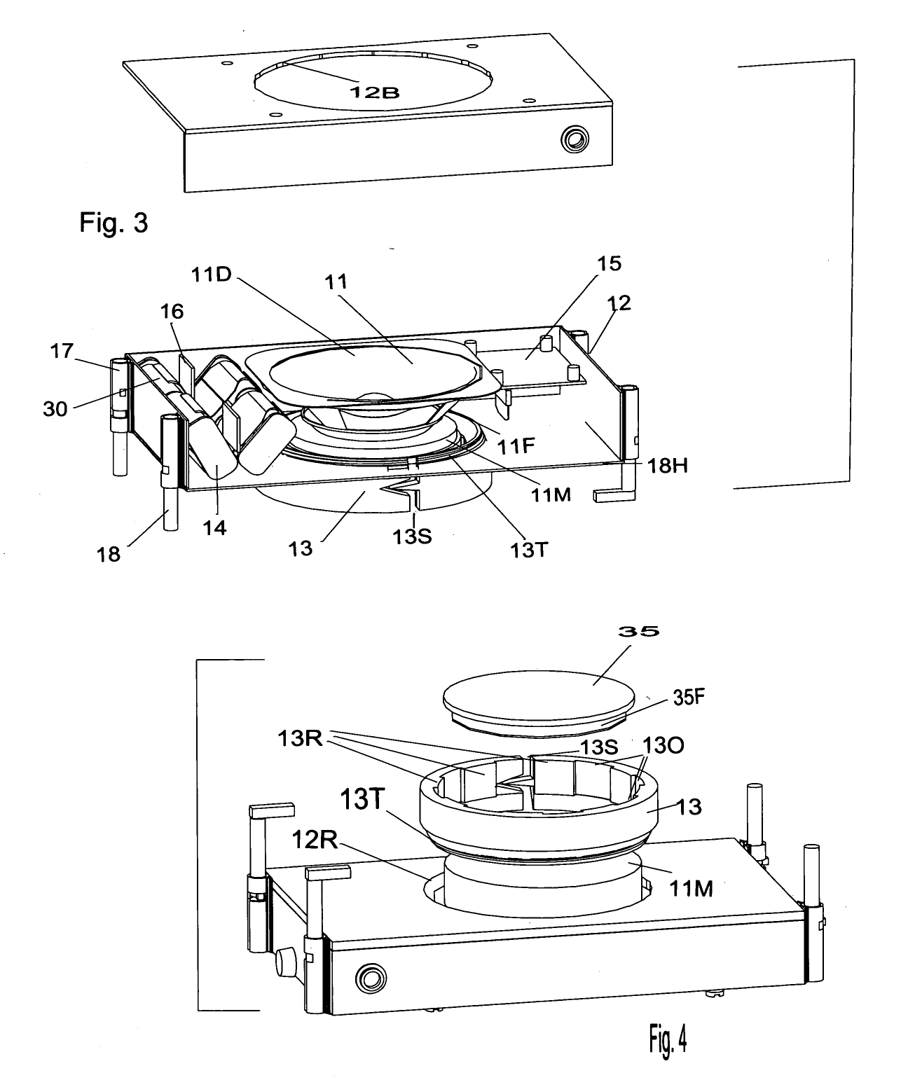

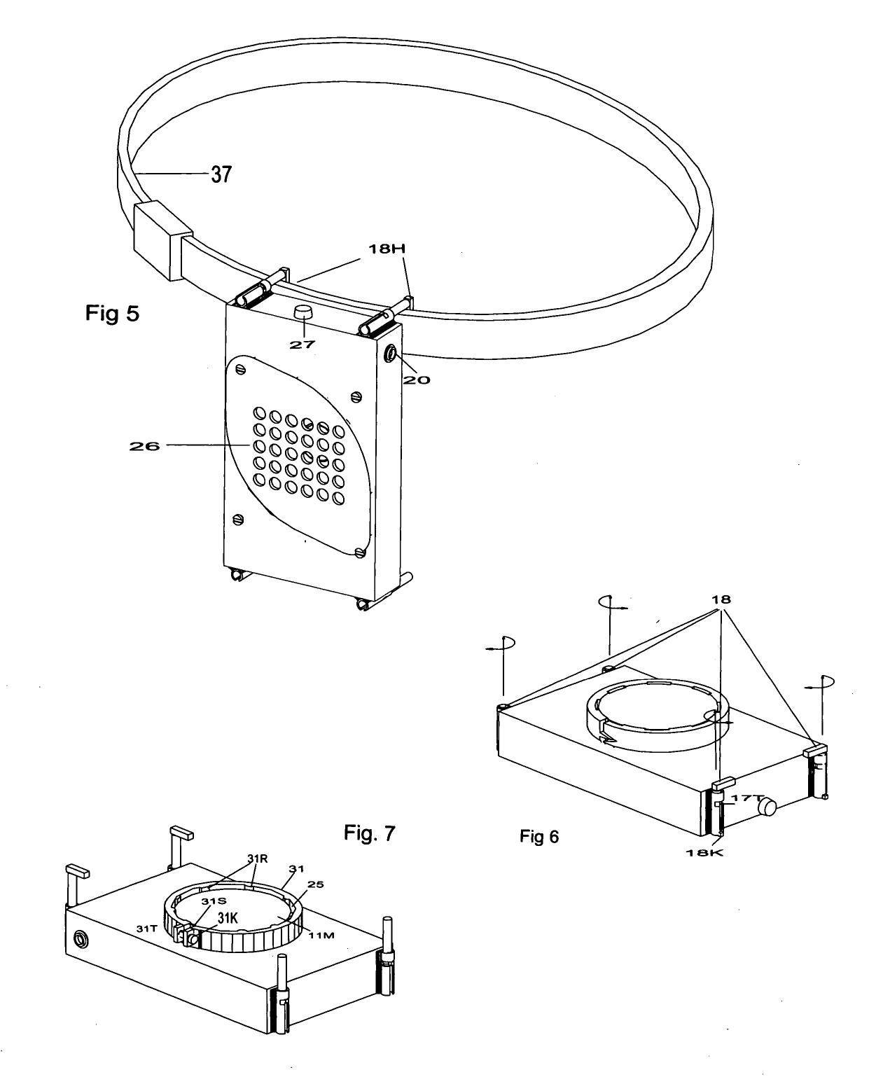

FIGS. 1 and 2 or overhead views of the invention, and show it in its primary operating position on some sort of table or other flat surface. FIG. 3 is an exloded view with the cabinet walls separated to reveal the internal components. It shows all the standard components utilized in previous self-contained and portable amplifier/loudspeaker devices including loudspeaker, cabinet, amplifier electronics, and batteries.

However, where previous designs allow sufficient space for all these components to be fully enclosed within the cabinet, this invention allows part of the speaker, which in this case is exclusively the loudspeaker's magnet assembly lie outside of a much shallower main cabinet 12 than in previous design which would tend to be much closer to a cube shape. In accordance with present invention this results in the speaker magnet assembly 11M protruding through the opening 12R provided for it in the side of cabinet opposite the side having the enclosure baffle 12B and to which the front of the speaker 11 is fastened in the conventional manner having the speaker's axis of vibration primarily perpendicular to the the cabinets baffle and the side opposite and parallel to it.

In accordance with a crucial element of the invention, extending from the cabinet's rear opening 12R is a hollow extension 13 which is acoustically connected to the cabinet and in addition, surrounds the speaker magnet 11M. Also in accordance with the invention, the difference in cross sectional area between the hollow extension 13 and the speaker magnet 11M are what primarily determine the acoustic resistance of the passage and cabinet port which is created between them. To facilitate an important feature of the preferred embodiment, a mechanism for slightly altering the diameter of the extension, a slit or break 13S in the ring-shaped extension accommodates for the change in circumference resulting from the adjustment. Also helping to facilitate this feature, a number of ribs 13R extend radially inward from the inside diameter of the hollow extension 13 and make contact with the magnet 11M when inward force to the hollow extension is applied and thereby prevent i13 from collapsing on the magnet if too much adjustment force were applied. Air in the form of sound pressure waves is allowed to flow from the cabinet which contains the loudspeaker diaphragm through the openings 13O between the ribs 13R. The ribs allow the gap of the air passage to be consistent from unit to unit and thereby, the acoustic resistance of the port to remain relatively consistent as well for what would be factory determined optimal acoustic resistance of the port for best performance. In practice, this is important, because the standard method of manufacture of these ring magnets allows their outside diameter to vary by around 1% which, for a magnet outside diameter of 80 mm and the typical small distance between magnet the inside of the tube, might cause the acoustic resistance of the port to vary by more than 100% if the diameter of tube were fixed. Another means of operation would be to allow variation of the extension diameter greater than that needed to accommodate the variations in magnet diameter to allow some degree of acoustic tuning by the user. In the case of a lowered acoustic restriction, the ribs would not contact the magnet.

The ribs serve to maintain the correct gap when a means of adjusting the diameter of the tube 13 is provided. In the preferred embodiment this is accomplished by creating an narrow opening in the ring parallel, and running the entire length of the ring which allows the ring, which is made of a slightly to moderately flexible material to change its diameter enough to provide for the variations in magnet interface diameter.

This cabinet extension 13 for FIGS. 1, 2, 3, 4, 6 or 31 in FIG. 7, has several effects as it serves to house the speaker's magnet. It creates a port which allows sound to project from its opposite side of the cabinet through the extension's 13 exhaust hole 13E. while providing an appropriate amount of acoustic restriction needed for the oversize speaker thereby improving low frequency performance by both smoothing and lowering the resonance frequency peak generated by the use of a small enclosure. It keeps the loudspeaker magnet 11M from being contacting and affecting information on magnetic media which might be carried along with the amp in the same. The optimization of the device for the use of a large speaker magnet allows the use of loudspeaker driver of much higher efficiency for the bulk of the device.

In the preferred embodiment there is an adjustment for varying the width of hollow extension, which may be made of strong but elastic material providing its own restoring force to push against the inward force of the adjustment mechanism and allow the width of the hollow cabinet extension to properly complement the speaker magnet diameter, and especially to allow the manufacturing of the device to deal with the small variations in magnet size encountered in typical loudspeaker manufacturing. Two examples of how this can be accomplished are shown. In FIG. 7 a pair of tabs 31T attached to the outside diameter of the cabinet extension 31 and a threaded tightening knob 31K pulls the tabs together thus reducing ring's diameter. In FIGS. 1, 2, 3, 4 and 6, a tapered diameter thread 13H ,being somewhat similar to pipe thread except that the mating thread is not tapered, at the attachment side of the extension 13 which causes the tube 13 to tighten around the magnet 11M when screwed into the rear cabinet opening 12R. A plastic cover 35 is used over the rear face of the magnet which prevents direct contact with magnetic storage devices such as floppy disks and audio cassette tapes. This cover is the same size as the outside diameter of the loudspeaker magnet 11M and centered by the enclosure extension ribs 13R/31R and, therefore, does not impede airflow through the air gaps 13O (FIGS. 4, 6). A disc of plastic with a thin ferrous sheet 35F attached to it with plastic facing outward is held in place by the magnet itself. 8 AA(UM-3) NiMH 30 are enclosed in the cabinet 12 along side of the speaker 11. The cutaway view in FIG. 3 shows the use of an integrated circuit audio amplifier and two battery holders 14 each holding 4 batteries and oriented at an angle towards one another in order to create the smallest possible combination of width(footprint) and height. The battery rest 16, the loudspeaker frame 11F, and the cabinet 12 support the batteries in this position.

Retractable legs 18 which slide through leg guides 17 are attached to the ends of the cabinet and, when extended, allow the speaker to point face up and supply enough clearance 33 from the cabinet extension 13/31 from the table 36 on which the device is placed, to allow acoustic energy emanating from the hollow extension to reflect off the table 36.

Retractable legs 18 slide in the slotted track 17T of leg guides 17. The guides are rigidly attached to the cabinet 12. The legs can be locked in place at the normal operating position which places the distance from both the bottom of the cabinet and the exhaust of the cabinet extension at some predetermined optimum distance from the table 36 or other surface upon which the device rests, and additional detents may also be provided to allow the player to vary the sound produced to his taste.

A very simple limiting circuit also mount on PCB 15 which needs to monitors input/electronics output voltage and reduces the internal amplifier gain at some threshold which might otherwise cause the sound to distort. Since many electric guitarists will play individual note musical figures a great deal of the time, this allows the amp to operate at a higher volume, because the huge surges in voltage caused by chords being struck are prevented from overloading the the amplifier and also extends battery life. A simple bridge rectifier and capacitor to convert the AC music signal to a DC voltage and a single stage voltage comparator are used to accomplish this purpose.

In the preferred embodiment, the main cabinet 12 is made of a plastic which is somewhat softer than that used for electronics enclosures for the purpose of allowing some sympathetic vibration in order to increase the amp's volume, but is of a slightly rubbery quality which avoids particularly offensive resonances of the enclosure which might be created by a harder plastic keeping the sound radiated as natural as possible for a device of its type.

Operation

The invention's principal mode of operation and the way it is primarily, although not exclusively, intended to be used is with the legs 18 extended and locked and placed on a table 36 supported by the legs as shown in FIGS. 1 and 2. The electronic instrument, typically an electric guitar, is connected to the invention's input jack using a conventional guitar cable. Sound is projected from the upward facing loudspeaker 11 and also reflected off the table 36 on which the amp is supported, since sound energy is passed downward between the downward facing loudspeaker magnet 11M and enclosure extension (13 or 31). For transport, the legs are conveniently retracted to reduce the amplifier's bulk.

The invention may also be played be the player while he is standing by extending the hooked legs and hooking them over the players pants belt as in FIG. 7. The volume produced when used this way will be somewhat less than that achieved when operated on a hard surface such as a table or floor, because sound energy emanating from the cabinet extension (13 or 31) will be absorbed by the soft surfaces of the player and his clothing. FIG. 7 also shows 2 important components, the musical instrument input jack 20 and an electronics switch/control both which are face upward towards the player when the disclosed invention is used or worn on this manner.

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

Drawing part number global reference

| number | part short name |
|---|---|
| 11 | loudspeaker |
| 11M | loudspeaker magnet |
| 11D | loudspeaker diaphram |
| 11F | loudspeaker's frame |
| 12 | Main enclosure |
| 12B | Cabinet baffle |
| 12R | Cabinet rear opening |
| 13 | Cabinet extension |
| 13H | Threads of cabinet Extension |
| 13O | Opening between ribs of cabinet extension |
| 13R | Rib on cabinet extension |
| 13S | Slit in cabinet Extension |
| 14 | batterholder (X2) |
| 15 | electronics PCB |
| 16 | battery holder rest |
| 17 | leg guide (X4) |
| 17T | leg guide track |
| 18 | leg |
| 18K | Leg key |
| 18H | Leg hooks |
| 20 | Instrument input jack |
| 25 | Acoustic port of magnet and enclosure extension |
| 26 | Speaker Grill |
| 27 | Amplifier electronics control/switch |
| 29 | Speaker Mounting screws (4×) |
| 30 | battery |
| 31 | Tabbed enclosure extension |
| 31K | tension knob for tabbed cabinet extension |
| 31R | Rib of tabbed cabinet extension |
| 31S | Slit of tabbed cabinet Extension |
| 31T | Tab of tabbed cabinet extension |
| 33 | Space between cabinet and table/floor surface |
| 35 | Magnet protective rear cover |
| 35F | Magnet protective cap ferrous metal |
| 36 | Table or floor |
| 37 | Player's belt |

1. Portable Musical Instrument Amplifier comprising:
A shallow main enclosure which is shaped to house the electronics, a battery supply, and only the diaphram section of a dynamic loudspeaker;
A speaker mounted normal to the two largest sides of the shallow cabinet, this side to be used as the conventional baffle;
A speaker magnet which lies outside of this main enclosure due to the shallow form of the cabinet;
An extension to this main enclosure cabinet which allows cabinet's internal volume to be be extended just sufficiently to surround the speaker magnet;
An air passage created by the difference in cross-sectional area of the extension and the magnet it surrounds.;
An opening in the extension which exhausts the acoustuc energy flowing around the magnet to the ambient space; and

2. A device as claimed in 1 wherein the cabinet is positioned with the exhaust of its extension in close proximity to the surface upon which the device is supported with the larger planes of the main cabinet held essentially parallel to its supporting surface.

3. A device as claimed in 1 wherein there is a mechanism for applying an inward force to the cabinet extension cabable of reducing the cross-sectional area of the extension

4. A device as claimed in 1 wherein the cabinet extension has a set of ribs on it inside diameter which prevent the extension from collapsing onto the magnet when as inward force is applied to the extension

5. A device as claimed in 1 wherein there is a means of supporting the device in such a position that the main enclosure is approximately parallel to the supporting surface causing acoustic energy to reflect from the supporting surface

6. A device as claimed in 1 wherein an adjustment to the support mechanism will vary the distance from the bottom of the amplifier, the side with the magnet and acoustic port to the supporting surface for the purpose of optimizing the sound pressure between these 2 closely spaced essentially parallel surfaces as well as reduce the overall dimension of the device for ease of its transport.

7. A device as claimed in 1 wherein an electronic limiting circuit is employed for the purpose of maximizing the useful volume range of the amplifier by allowing use at high gain without the risk of overload during performance crescendos and to improve battery longevity.

8. A device as claimed in 1 wherein the main cabinet is fabricated from a somewhat non-rigid material for the purpose of using its sympathetic vibration to further increase efficiency and maximum volume obtainable from the small cabinet

9. The incorperation of hooks on the leg supports for the purpose of being able to operate while being hung from the players belt.
